(19) United States
(12) Patent Application Publication
(10) Pub. No.: US 2025/0247069 A1
(43) Pub. Date: Jul. 31, 2025

(54) MULTILAYER PIEZOELECTRIC SUBSTRATE ACOUSTIC WAVE DEVICE INCLUDING MULTIPLE PIEZOELECTRIC MATERIAL LAYERS DISPOSED ON QUARTZ SUBSTRATE AND UTILIZING BURIED ELECTRODES

(71) Applicant: SKYWORKS SOLUTIONS, INC., Irvine, CA (US)

(72) Inventor: Rei Goto, Osaka-Shi (JP)

(21) Appl. No.: 19/038,882

(22) Filed: Jan. 28, 2025

Related U.S. Application Data
(60) Provisional application No. 63/626,396, filed on Jan. 29, 2024.

(51) Int. Cl. H03H 9/02; H03H 9/145; H03H 9/25

(52) U.S. Cl. CPC H03H 9/02574; H03H 9/02551; H03H 9/02559; H03H 9/14541; H03H 9/25

(57) ABSTRACT

Aspects and embodiments disclosed herein include a surface acoustic wave device comprising a quartz substrate, a layer of a first lithium-based piezoelectric material disposed on an upper surface of the quartz substrate, a layer of a second lithium-based piezoelectric material formed of a material different from the first lithium-based piezoelectric material disposed on an upper surface of the layer of the first lithium-based piezoelectric material, and interdigital transducer electrodes disposed on an upper surface of the layer of the second lithium-based piezoelectric material.

### CROSS-REFERENCE TO RELATED APPLICATIONS

This application claims priority under 35 U.S.C. § 119 (e) to U.S. Provisional Patent Ser. No. 63/626,396, titled “MULTILAYER PIEZOELECTRIC SUBSTRATE ACOUSTIC WAVE DEVICE INCLUDING MULTIPLE PIEZOELECTRIC MATERIAL LAYERS DISPOSED ON QUARTZ SUBSTRATE AND UTILIZING BURIED ELECTRODES,” filed Jan. 29, 2024, the entire content of which is incorporated herein by reference for all purposes.

### BACKGROUND

### Field

Aspects and embodiments disclosed herein relate to multilayer piezoelectric substrate (MPS) devices, and in particular to MPS acoustic wave devices with an embedded interdigital transducer (IDT) structure and multiple piezoelectric material layers.

### Description of Related Technology

An acoustic wave device can include a plurality of resonators arranged to filter a radio frequency signal. Examples of acoustic wave resonators include surface acoustic wave (SAW) resonators. A surface acoustic wave resonator can include an interdigital transducer (IDT) electrode on a piezoelectric substrate. The surface acoustic wave resonator can generate a surface acoustic wave on a surface of the piezoelectric layer on which the interdigital transducer electrode is disposed.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

### SUMMARY

In accordance with one aspect, there is provided a surface acoustic wave (SAW) device comprising a quartz substrate, a layer of a first lithium-based piezoelectric material disposed on an upper surface of the quartz substrate, a layer of a second lithium-based piezoelectric material formed of a material different from the first lithium-based piezoelectric material disposed on an upper surface of the layer of the first lithium-based piezoelectric material, and interdigital transducer electrodes disposed on an upper surface of the layer of the second lithium-based piezoelectric material.

In some embodiments, the first lithium-based piezoelectric material is lithium tantalate.

In some embodiments, the lithium tantalate has a cut angle in a range from 10° to 50°.

In some embodiments, the second lithium-based piezoelectric material is lithium niobate.

In some embodiments, the layer of lithium niobate is thinner than the layer of lithium tantalate.

In some embodiments, the quartz substrate is thicker than a combined thickness of the layer of lithium niobate is thinner and the layer of lithium tantalate.

In some embodiments, the quartz substrate has a cut angle in a range from 20° to 52°.

In some embodiments, the SAW device further comprises a layer of the second lithium-based piezoelectric material disposed on upper surfaces of the interdigital transducer electrodes.

In accordance with another aspect, there is provided a surface acoustic wave (SAW) device comprising a quartz substrate, a layer of a first lithium-based piezoelectric material disposed on an upper surface of the quartz substrate, and interdigital transducer electrodes at least partially buried in the layer of the first lithium-based piezoelectric material.

In some embodiments, the first lithium-based piezoelectric material is lithium tantalate.

In some embodiments, the interdigital transducer electrodes are multi-layer electrodes including a lower layer and an upper layer disposed on an upper surface of the lower layer, the lower layer of the interdigital transducer electrodes at least partially buried within the layer of the first lithium-based piezoelectric material, the upper layer of the interdigital transducer electrodes disposed at a height above an upper surface of the layer of the first lithium-based piezoelectric material.

In some embodiments, the SAW device further comprises a layer of a second lithium-based piezoelectric material formed of a material different from the first lithium-based piezoelectric material and disposed on an upper surface of the layer of the first lithium-based piezoelectric material.

In some embodiments, the interdigital transducer electrodes are multi-layer electrodes including a lower layer and an upper layer disposed on an upper surface of the lower layer, the lower layer of the interdigital transducer electrodes at least partially buried within the first layer of lithium-based piezoelectric material and the second layer of lithium-based piezoelectric material.

In some embodiments, the SAW device further comprises a second layer of the second lithium-based piezoelectric material disposed on upper surfaces of the interdigital transducer electrodes.

In accordance with another aspect, there is provided a surface acoustic wave (SAW) device comprising a support substrate, a layer of a first lithium-based piezoelectric material disposed above an upper surface of the support substrate, a layer of a second lithium-based piezoelectric material formed of a material different from the first lithium-based piezoelectric material disposed on an upper surface of the layer of the first lithium-based piezoelectric material, and interdigital transducer electrodes at least partially buried within the layer of the second lithium-based piezoelectric material.

In some embodiments, the first lithium-based piezoelectric material is lithium tantalate.

In some embodiments, the second lithium-based piezoelectric material is lithium niobate.

In some embodiments, the interdigital transducer electrodes are at least partially buried within the layer of the first lithium-based piezoelectric material and the layer of the second lithium-based piezoelectric material.

In some embodiments, the interdigital transducer electrodes are multi-layer electrodes including a lower layer and an upper layer disposed on an upper surface of the lower layer, the lower layer of the interdigital transducer electrodes at least partially buried within the layer of the second lithium-based piezoelectric material, the upper layer of the interdigital transducer electrodes disposed at a height above an upper surface of the layer of the second lithium-based piezoelectric material.

In some embodiments, the interdigital transducer electrodes are multi-layer electrodes including a lower layer and an upper layer disposed on an upper surface of the lower layer, the lower layer of the interdigital transducer electrodes at least partially buried within the layer of the first lithium-based piezoelectric material and the layer of the second lithium-based piezoelectric material, the upper layer of the interdigital transducer electrodes disposed at a height above an upper surface of the layer of the second lithium-based piezoelectric material.

In some embodiments, the SAW device is included in a radio frequency filter.

In some embodiments, the radio frequency filter is included in a radio frequency device module.

In some embodiments, the radio frequency device module ins included in a radio frequency device.

### BRIEF DESCRIPTION OF THE DRAWINGS

FIG. 1A is a cross sectional view of a portion of a SAW device having an IDT structure arranged on a piezoelectric layer;

FIG. 1B is an enlarged view of the encircled portion of the IDT shown in FIG. 1A;

FIG. 1C is a top view on a SAW device having the IDT structure illustrated in FIG. 1A;

FIG. 2A is a cross-sectional view of a portion of a SAW device with a partially embedded IDT structure having two layers of Mo and Al or two layers of Cu and Al;

FIG. 2A′ is an enlarged view of the encircled portion of the IDT shown in FIG. 2A;

FIG. 2B is a cross-sectional view of a portion of a SAW device with a partially embedded IDT structure having a layer of Cu, Pt, or Au where the IDT structure has a reverse tapered shape;

FIG. 2B′ is an enlarged view of the encircled portion of the IDT shown in FIG. 2B;

FIG. 2C is a cross-sectional view of a portion of a SAW device with a partially embedded IDT structure having layered electrodes with a lower layer having a reverse tapered shape and an upper layer having a tapered shape;

FIG. 3A illustrates three plots of static coupling (left frame), k²_{eff} (middle frame), and resonance frequency fs (right frame) versus embedment depth d_{embed}/λ for different heights h_{Mo} of a Mo layer in the range 0.02≤h_{Mo}/λ0.08, fixed height h_{Al} of an Al layer at h_{Al}/λ=0.08, and fixed LT cut angle for XY—LiTaO₃ at 42°, as obtained from a 2D simulation for the IDT structure presented in FIG. 2A and FIG. 2A′;

FIG. 3B illustrates three plots of static coupling (left frame), k²_{eff} (middle frame), and resonance frequency fs (right frame) versus embedment depth d_{embed}/λ for different heights h_{Al} of an Al layer in the range 0.04≤h_{Al}/λ≤0.08, a fixed height h_{Mo} of a Mo layer at h_{Mo}/λ=0.02, and fixed LT cut angle for XY—LiTaO₃ at 42°, as obtained from a 2D simulation for the IDT structure presented in FIG. 2A and FIG. 2A′;

FIG. 3C illustrates a plot of k²_{eff} versus embedment the LT cut angle for XY—LiTaO₃ for different embedment depths d_{embed}/λ in the range 0.00≤d_{embed}/λ≤0.08, a fixed height h_{Mo} of a Mo layer at h_{Mo}/λ=0.02, and a fixed height h_{Al} of an Al layer at h_{Al}/λ=0.04, as obtained from a 2D simulation for the IDT structure presented in FIG. 2A and FIG. 2A′;

FIG. 4A is a plot of admittance Y(dB) versus frequency f (GHz) for IDT structures with different embedment depths d_{embed}/λ as obtained from a 3D simulation for IDT structures in accordance with the structures shown in FIG. 2A and FIG. 2A′;

FIG. 4B is a plot of conduction G(dB) versus frequency f (GHz) for IDT structures with different embedment depths d_{embed}/λ as obtained from a 3D simulation for IDT structures in accordance with the structures shown in FIG. 2A and FIG. 2A′;

FIG. 4C is a plot of the Quality factor Q versus frequency f (GHz) for IDT structures with different embedment depths d_{embed}/λ as obtained from a 3D simulation for IDT structures in accordance with the structures shown in FIG. 2A and FIG. 2A′;

FIG. 5A is a cross-sectional view of a portion of a SAW device having multiple layers of piezoelectric material and single layer IDT electrode fingers disposed on top of the upper layer of piezoelectric material;

FIG. 5B is a cross-sectional view of a portion of a SAW device having multiple layers of piezoelectric material and multi-layer IDT electrode fingers partially buried in the layers of piezoelectric material;

FIG. 5C is a cross-sectional view of a portion of a SAW device having multiple layers of piezoelectric material and single layer IDT electrode fingers partially buried in the layers of piezoelectric material;

FIG. 5D is a cross-sectional view of a portion of a SAW device having multiple layers of piezoelectric material and multi-layer IDT electrode fingers partially buried in the layers of piezoelectric material;

FIG. 5E is a cross-sectional view of a portion of a SAW device having multiple layers of piezoelectric material and single layer IDT electrode fingers disposed on top of the upper layer of piezoelectric material;

FIG. 5F is a cross-sectional view of a portion of a SAW device having multiple layers of piezoelectric material, single layer IDT electrode fingers disposed on top of the upper layer of piezoelectric material, and a trap rich layer disposed on a support substrate;

FIG. 5G is a cross-sectional view of a portion of a SAW device having multiple layers of piezoelectric material, multi-layer IDT electrode fingers partially buried in the layers of piezoelectric material, and a trap rich layer disposed on a support substrate;

FIG. 6 is a graph showing simulated admittance results of a baseline SAW device and the SAW device of FIG. 5F

FIG. 7 is a graph showing simulated coupling factor k² results of the SAW device of FIG. 5F;

FIG. 8A is a graph showing simulated coupling factor k² results of the baseline SAW device and the SAW device of FIG. 5F simulated with various YX-cut angles;

FIG. 8B is a graph showing results of simulated resonant temperature coefficient of frequency (TCF) relative to coupling factor k² of the SAW device of FIG. 5F;

FIG. 8C is a graph showing results of simulated anti-resonant TCF relative to coupling factor k² of the SAW device of FIG. 5F;

FIG. 8D is a graph showing simulated results of difference in TCF relative to coupling factor k² of the SAW device of FIG. 5F;

FIG. 9A is a cross-sectional view of a portion of a SAW device having multiple layers of piezoelectric material, multi-layer IDT electrode fingers disposed on top of the upper layer of piezoelectric material, and a layer of piezoelectric material disposed on top of the IDT electrode fingers;

FIG. 9B is a cross-sectional view of a portion of a SAW device having multiple layers of piezoelectric material, multi-layer IDT electrode fingers partially buried within the multiple layers of piezoelectric material, and a layer of piezoelectric material disposed on top of the IDT electrode fingers;

FIG. 10A is a cross-sectional view of a portion of a SAW device having a quartz substrate, a layer of piezoelectric material disposed on the quartz substrate, and multi-layer IDT electrode fingers partially buried within the layer of piezoelectric material;

FIG. 10B is a cross-sectional view of a portion of a SAW device having a quartz substrate, multiple layers of piezoelectric material disposed on the quartz substrate, and multi-layer IDT electrode fingers partially buried within the multiple layers of piezoelectric material;

FIG. 10C is a cross-sectional view of a portion of a SAW device having a quartz substrate, multiple layers of piezoelectric material disposed on the quartz substrate, and multi-layer IDT electrode fingers disposed on top of the multiple layers of piezoelectric material;

FIG. 10D is a cross-sectional view of a portion of a SAW device having a quartz substrate, multiple layers of piezoelectric material disposed on the quartz substrate, multi-layer IDT electrode fingers disposed on top of the multiple layers of piezoelectric material, and a layer of piezoelectric material disposed on top of the multi-layer IDT electrode fingers;

FIG. 10E is a cross-sectional view of a portion of a SAW device having a quartz substrate, multiple layers of piezoelectric material disposed on the quartz substrate, multi-layer IDT electrode fingers partially buried in the multiple layers of piezoelectric material, and a layer of piezoelectric material disposed on top of the multi-layer IDT electrode fingers;

FIG. 11 is a schematic diagram of a radio frequency ladder filter;

FIG. 12 is a block diagram of one example of a filter module that can include one or more acoustic wave elements according to aspects of the present disclosure;

FIG. 13 is a block diagram of one example of a front-end module that can include one or more filter modules according to aspects of the present disclosure; and

FIG. 14 is a block diagram of one example of a wireless device including the front-end module of FIG. 13.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can implement bandpass filters. For example, a bandpass filter can be formed from temperature compensated surface acoustic wave (TCSAW) resonators.

Parameters of acoustic wave filters desired by customers include small size, low change in performance, for example, passband frequency, with changes in temperature, often referred to as low temperature coefficient of frequency (TCF), high quality factor (Q), low insertion loss, and large bandwidth with steep passband edges to accommodate newer high bandwidth radio frequency communication bands. The bandwidth of an acoustic wave filter is related to the electromechanical coupling coefficient (k²) of acoustic wave resonators included in the filter.

Typical lithium tantalate (LiTaO₃, LT) based multilayer piezoelectric substrate (MPS) SAW filter packages have an upper limit for k² of around 12%. This value is higher than the k² that may be obtained with a 128° lithium niobate (LiNbO₃, LN) based MPS SAW filter package. However, this k² value is still smaller than would be desired to provide a MPS SAW filter with a desirably wide passband with good insertion loss.

To provide a solution with a high k² and a high Q, LT based MPS SAW filter packages with an embedded or partially buried interdigital transducer (IDT) structure are proposed. Size reduction due to a large static capacitance between IDT electrode fingers of the SAW resonators included in such filters may be achieved by embedding the IDT in a high permittivity piezoelectric substrate.

While example SAW devices will now be discussed, the devices and methods disclosed herein can apply to other types of acoustic wave devices, including boundary wave devices and Lamb wave devices, for example.

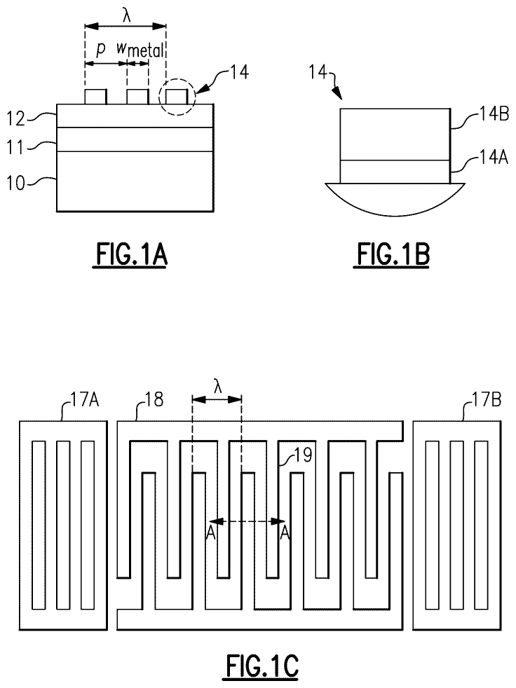

FIG. 1A is a cross sectional view of an interdigital transducer (IDT) structure 14 of a section of a SAW device having an IDT structure arranged on a piezoelectric layer 12. The SAW device can be a TCSAW resonator. The terms “SAW resonator” and “SAW device” are used synonymously herein unless the context indicates that a different form of device is being referenced. As illustrated, the SAW device includes a piezoelectric layer 12 formed over a functional layer 11, which can be made of silicon dioxide (SiO₂), for example, and IDT electrodes 14. The SiO₂ layer may be formed on a support substrate 10. The support substrate 10 may be formed of, for example, silicon, aluminum nitride, sapphire, or another suitable material. The TCSAW device may comprise a temperature compensation layer over the IDT electrodes 14.

The piezoelectric layer 12 can be a lithium-based piezoelectric layer. For example, the piezoelectric layer 12 can be a lithium niobate (LN) layer. As another example, the piezoelectric layer 12 can be a lithium tantalate (LT) layer.

In the TCSAW device, the IDT electrode 14 is disposed on the piezoelectric layer 12. As illustrated, the IDT electrode 14 has a first side in physical contact with the piezoelectric layer 12 and a second side which may be in physical contact with the TC layer (not shown). The IDT electrode 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrode 14 can be a multi-layer IDT electrode in some embodiments. A ratio of the IDT width (wₘₑₜₐₗ) to the pitch (p) is usually defined as duty factor (DF) or metallization ratio (wₘₑₜₐₗ/p).

In the TCSAW device, the TC layer and/or the functional layer 11 can have a positive TCF. This can at least partially compensate for a negative TCF of the piezoelectric layer 12. The piezoelectric layer 12 can be lithium niobate or lithium tantalate, which both have a negative TCF. The TC layer and/or the functional layer 11 can be a dielectric film. The TC layer and/or the functional layer 11 can be a silicon dioxide (SiO₂) layer. In some other embodiments, a different TC layer can be implemented. Some examples of other TC layers include a tellurium dioxide (TeO₂) layer or a silicon oxyfluoride (SiOF) layer.

FIG. 1B is an enlarged view of the circled portion of the IDT electrode 14 shown in FIG. 1A. In the example shown in FIG. 1B, the IDT electrode 14 has two layers, for instance a layer 14A of molybdenum (Mo), and a layer 14B of aluminum (Al). The IDT 14 as a whole is arranged on the piezoelectric layer 12.

FIG. 1C is a top view on a SAW device having an IDT structure 14 as illustrated in FIG. 1A. In FIG. 1C, the view of the SAW devices shown in FIG. 1A or FIG. 1B is along the dashed line from A to A. The TC layer is not shown in FIG. 1C. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT fingers 19 extending from the bus bar 18. The IDT fingers 19 have a pitch of p=λ/2, where λ denotes the wavelength of the resonant frequency fs of the SAW device. The SAW device can include any suitable number of IDT fingers 19. The pitch of the IDT fingers 19 corresponds to the resonant frequency fs of the SAW device.

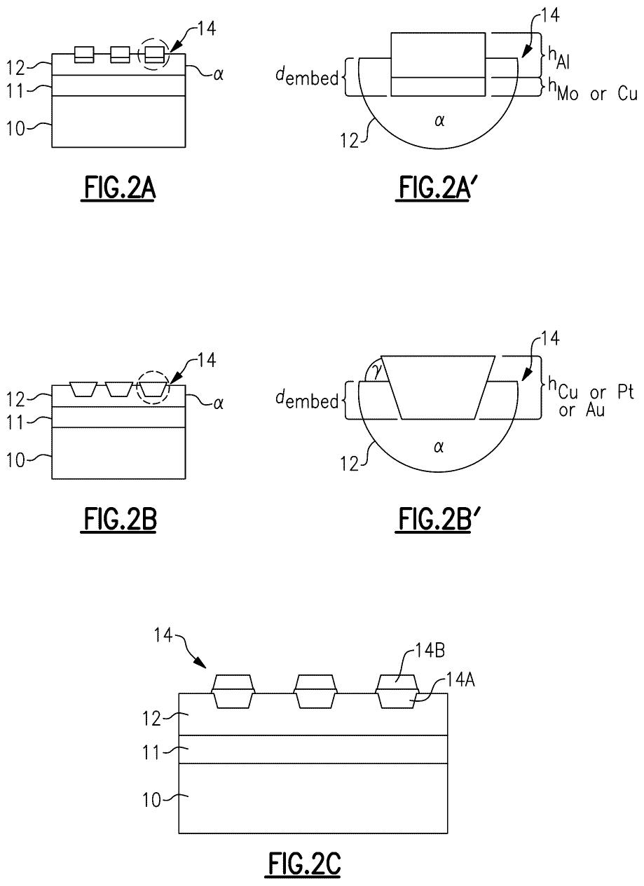

FIG. 2A is a cross-sectional view of an IDT structure of a section of a SAW device with a partially embedded IDT structure 14 having two layers 14A, 14B of Mo and Al, of Cu and Al, or of W and Al. The IDT structure 14 may be multi-layered in some applications. Mo, Cu, W, and Al are merely mentioned as examples.

The SAW device partly shown in FIG. 2A may comprise a support substrate 10, a layer of silicon dioxide (SiO₂) 11 formed on the support substrate 10, a piezoelectric layer 12 formed on the layer of SiO₂, and the partially embedded IDT structure 14. The piezoelectric layer 12 may comprise 42° XY—LiTaO₃ (42° XY-LT) or consist thereof. Alternatively or additionally, the piezoelectric layer 12 may comprise αXY-LT, or consist thereof, where α denotes the LT cut angle. The LT cut angle α may be in the range 0°≤α≤50°.

FIG. 2A′ is an enlarged view of the circled portion of the IDT 14 shown in FIG. 2A. As shown in FIG. 2A′, in the case of two layers of Mo and Al, the layer of Mo has a height h_{Mo}, and the layer of Al has a height h_{Al}. The height h_{Mo} of the Mo layer may be in the range 0.02≤h_{Mo}/λ≤0.08, where λ corresponds to the geometry described in FIG. 1C. The wavelength λ may be defined as the wavelength along an IDT propagation direction of a main mode. The main mode may be the mode that primally contributes to form the filter characteristics. The height h_{Al} of the Al layer may be in the range 0.04≤h_{Al}/λ≤0.08, where λ is defined as above.

In the case of two layers of Cu and Al, the layer of Cu has a height h_{Cu}. The height h_{Cu} of the Cu layer may be in the range 0.02≤h_{Cu}/λ≤0.08, where λ is defined as above. The height h_{Al} of the Al layer may be in the range 0.04≤h_{Al}/λ≤0.08, where λ is defined as above. Cu can be used instead of Mo. Cu plating is suitable for embedding the IDT structure. Acoustic properties of Cu and Mo are similar.

The IDT structure 14 has an embedment depth d_{embed}. The embedment depth d_{embed} in the piezoelectric layer 12 may be in the range 0.00≤d_{embed}/λ≤0.10, where λ is defined as above.

FIG. 2B is a cross-sectional view of an IDT structure of a section of a SAW device with a partially embedded IDT structure 14 having a layer of Cu, Pt, or Au where the IDT structure 14 has a reverse tapered shape. The reverse tapered IDT structure 14 may be multi-layered in some embodiments. Cu, Pt, or Au are merely mentioned as examples.

The SAW device partly shown in FIG. 2B may comprise a support substrate 10, a layer of silicon dioxide (SiO₂) 11 formed on the support substrate 10, a piezoelectric layer 12 formed on the layer of SiO₂, and the partially embedded IDT structure 14. The piezoelectric layer 12 may comprise 42° XY—LiTaO₃ (42° XY-LT) or consist thereof. Alternatively or additionally, the piezoelectric layer 12 may comprise αXY-LT, or consist thereof, where α denotes the LT cut angle. The LT cut angle α may be in the range 0°≤α≤50°.

FIG. 2B′ is an enlarged view of the encircled portion of the IDT 14 shown in FIG. 2B. As shown in FIG. 2B′, the layer of Cu, Pt, or Au has a height h_{Cu or Pt or Au}. The height h_{Cu or Pt or Au} of the Cu, Pt, or Au layer may be in the range 0.06≤h_{Cu or Pt or Au}/λ≤0.16, where λ corresponds to the geometry described in FIG. 1C. The wavelength λ may be defined as the wavelength along an IDT propagation direction of a main mode. The main mode may be the mode that primarily contributes to form the filter characteristics.

The reverse tapered IDT structure 14 has an embedment depth d_{embed}. The embedment depth d_{embed} in the piezoelectric layer 12 may be in the range 0.00<d_{embed}/λ≤0.16, where λ is defined as above. The reverse tapered IDT structure 14 may be fully embedded or formed in the piezoelectric layer 12.

The reverse tapered IDT structure 14 may have a reverse taper angle γ with respect to the surface of the piezoelectric layer 12. The reverse taper angle γ may be in the range 65°≤γ≤90°, for example, 75°. Different sides of the reverse tapered IDT structure 14 may have different reverse taper angles.

The reverse tapered IDT structure 14 may be formed starting out from SiO₂ or amorphous Si deposition on LT layer. The resulting substrate may be dry etched to form the shape of the reverse tapered IDT structure. A seed layer may then be deposited, followed by electroplating and planarization. In the case of amorphous Si, XeF₂ gas may be used to remove amorphous Si.

FIG. 2C is a cross-sectional view of an IDT structure of a section of a SAW device with a partially embedded IDT structure 14 similar to that of FIGS. 2B and 2B′ but where the electrode fingers of the IDT structure 14 are multi-layered. A lower layer 14A of the electrode fingers of the IDT structure 14 has a reverse tapered cross-sectional shape (like a trapezoid with the smaller parallel side on the bottom) and may be partially or wholly embedded in the piezoelectric layer 12. The lower layer 14A of the electrode fingers may extend into the piezoelectric material layer 12 by, for example, about 10 nm. A flat non-tapered portion of the lower layer 14A of the electrode fingers may be disposed on top of the piezoelectric layer 12 with the tapered portion centered below the non-tapered portion. An upper layer 14N of the electrode fingers of the IDT structure 14 has a tapered cross-sectional shape (like a trapezoid with the longer parallel side on the bottom) and is disposed on top of the lower layer 14A.

The materials of the lower layer 14A and the upper layer 14B may be different and in non-limiting examples, may include or consist of one or more of Al, Ti, Ni, Mo, W, Cu, Pt, Ru. In some embodiments, the lower layer 14A is formed of a material with a higher density than the material of which the upper layer 14B is formed. In other embodiments, the reverse may be true—the lower layer 14A may be formed of a material with a lower density than the material of which the upper layer 14B is formed.

The taper angle of the sides of the upper layer 14B may be in the range of 65°-90°, for example, 75°. Different sides of the upper layer 14B may have different taper angles. The taper angle of the sides of the lower layer 14A and upper layer 14B may be the same as one another or different from one another.

While example SAW devices have been discussed with respect to FIGS. 2A-2C, aspects described with respect to the devices of FIGS. 2A-2C′ can apply to other types of acoustic wave devices, including boundary wave devices and Lamb wave devices. For example, boundary wave or Lamb wave devices can have layered structures in the similar or same arrangement of any of FIGS. 2A-2C and can have interdigital transducers partially or fully formed in the piezoelectric layer.

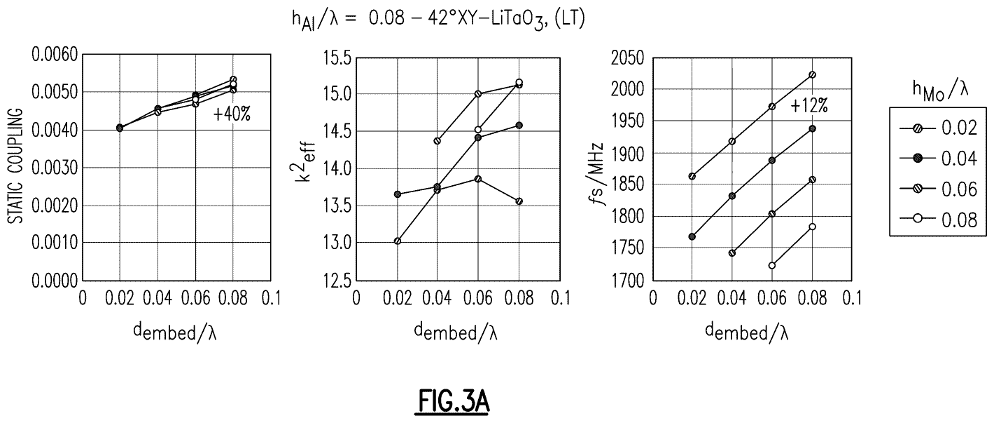

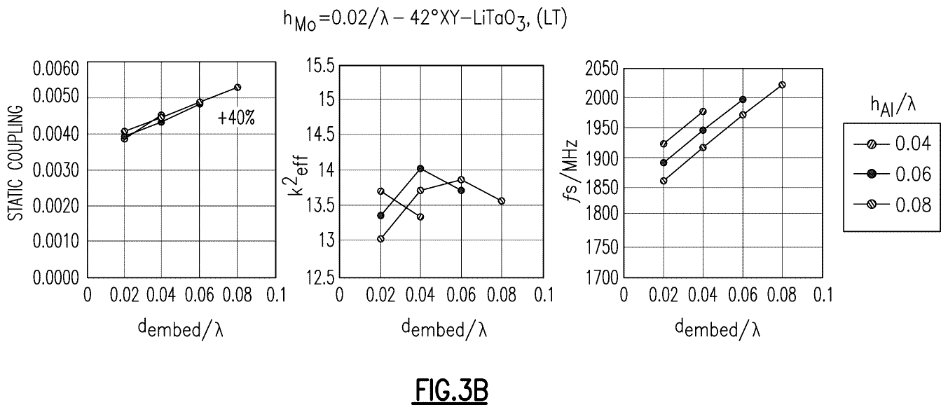

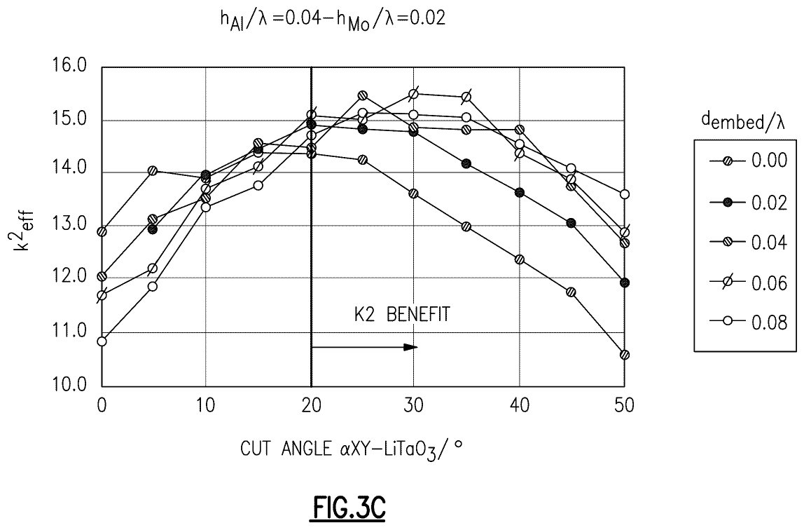

FIG. 3A illustrates three plots of static coupling (left frame), k² (middle frame), and resonance frequency fs (right frame) versus embedment depth d_{embed}/λ for different heights h_{Mo} of a Mo layer in the range 0.02≤h_{Mo}/λ≤0.08, fixed height h_{Al} of an Al layer at h_{Al}/λ=0.08, and fixed LT cut angle for XY—LiTaO3 at 42°, as obtained from a 2D simulation for the IDT structure presented in FIG. 2A and FIG. 2A′.

The left frame of FIG. 3A shows that embedding the IDT structure may lead to an increase of the static coupling of up to approximately 40% across the range of simulation. Hence, a size of the SAW device may be reduced. In the left frame of FIG. 3A, it can also be seen that the overall thickness of the IDT structure has little to no effect on the static coupling because the static coupling is essentially independent of the different heights h_{Mo} of the Mo layer used for the simulation.

The middle frame of FIG. 3A shows that embedding the IDT structure may lead to increase of k² and thus to a SAW device having an increased performance. A pass band of a filter utilizing SAW devices as disclosed herein may, for instance, be widened.

The right frame of FIG. 3A shows that embedding the IDT structure may lead to increased frequency (velocity) of up to approximately 12% the across range of simulation.

FIG. 3B illustrates three plots of static coupling (left frame), k² (middle frame), and resonance frequency fs (right frame) versus embedment depth d_{embed}/λ for different heights h_{Al} of an Al layer in the range 0.04≤h_{Al}/λ≤0.08, a fixed height h_{Mo} of a Mo layer at h_{Mo}/λ=0.02, and fixed LT cut angle for XY—LiTaO₃ at 42°, as obtained from a 2D simulation for the IDT structure presented in FIG. 2A and FIG. 2A′.

The left frame of FIG. 3B shows that embedding the IDT structure may lead to an increase of the static coupling of up to approximately 40% across the range of simulation. Hence, a size of the SAW device may be reduced. In the left frame of FIG. 3B, it can also be seen that the overall thickness of the IDT structure has little to no effect on the static coupling because the static coupling is essentially independent of the different heights h_{Al} of the Al layer used for the simulation.

The middle frame of FIG. 3B shows that embedding the IDT structure may lead to increase of k² and thus to the SAW device having an increased performance for as long as a threshold for the overall thickness of the IDT structure is not exceeded (note the regions in which the trace for h_{Al}/λ=0.08 is lower than the trace for h_{Al}/λ=0.06).

The right frame of FIG. 3B shows that embedding the IDT structure may lead to an increased frequency (velocity) where a thicker Al layer lowers the velocity. Hence, resistivity may be improved.

FIG. 3C illustrates a plot of k² versus embedment and LT cut angle for XY—LiTaO₃ for different embedment depths d_{embed}/λ in the range 0.00≤d_{embed}/λ≤0.08, a fixed height h_{Mo} of a Mo layer at h_{Mo}/λ=0.02, and a fixed height h_{Al} of an Al layer at h_{Al}/λ=0.04, as obtained from a 2D simulation for the IDT structure presented in FIG. 2A and FIG. 2A′.

As can be seen from FIG. 3C, with respect to embedment (d_{embed}/λ=0), k² is increased for any embedment depth d_{embed}/λ in the range of simulation for an LT cut angle α greater or equal than approximately 20°. As shown in FIG. 3C, k² above 13.0% was achieved for all simulated embedment depths for LT cut angles α greater or equal than approximately 10° and less than or equal to approximately 35°, and for all simulated embedment depths other than 0.00 for LT cut angles α greater or equal than approximately 10° and less than or equal to approximately 45°. Moreover, k² above 14.0% was achieved for all simulated embedment depths for LT cut angles α greater or equal than approximately 20° and less than or equal to approximately 25°, and for all simulated embedment depths other than 0.00 for LT cut angles α greater or equal than approximately 20° and less than or equal to approximately 35°.

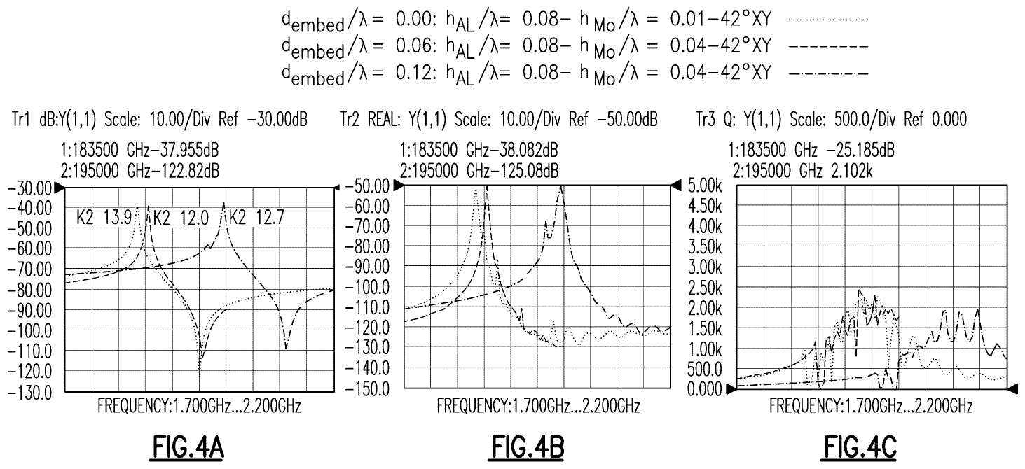

FIG. 4A is a plot of admittance Y(dB) versus frequency f (GHz) for IDT structures with different embedment depths d_{embed}/λ (no embedment, half embedded, and fully embedded) as obtained from a 3D simulation for IDT structures in accordance with the structures shown in FIG. 2A and FIG. 2A′.

FIG. 4B is a plot of conduction G(dB) versus frequency f (GHz) for IDT structures with different embedment depths d_{embed}/λ (no embedment, half embedded, and fully embedded) as obtained from a 3D simulation for IDT structures in accordance with the structures shown in FIG. 2A and FIG. 2A′.

FIG. 4C is a plot of the quality factor Q versus frequency f (GHz) for IDT structures with different embedment depths d_{embed}/λ (no embedment, half embedded, and fully embedded) as obtained from a 3D simulation for IDT structures in accordance with the structures shown in FIG. 2A and FIG. 2A′.

As can be seen from FIG. 4A to FIG. 4C in combination with the 2D simulations shown in FIG. 3A to FIG. 3C, a half embedded IDT structure has a benefit in k² and static capacitance. A quality factor for a half embedded IDT structure is approximately the same as the quality factor without embedment.

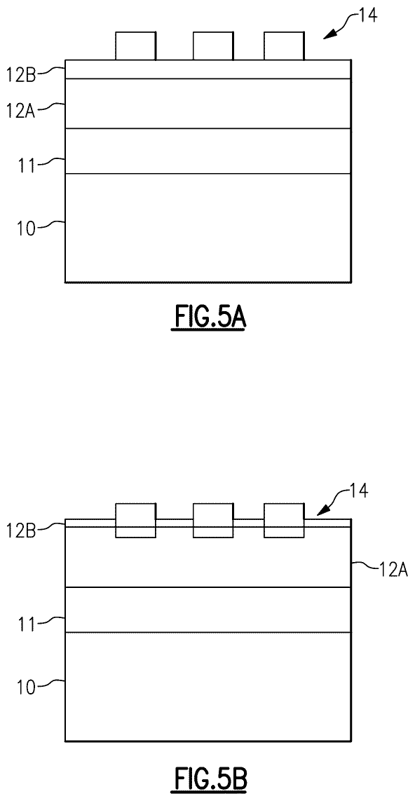

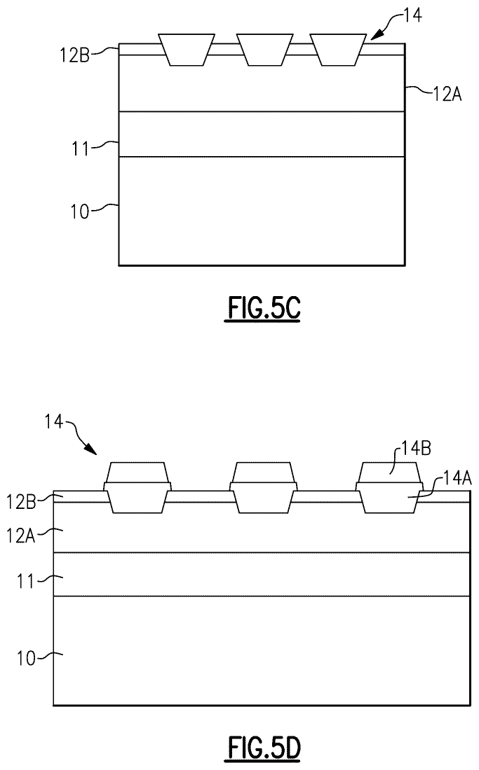

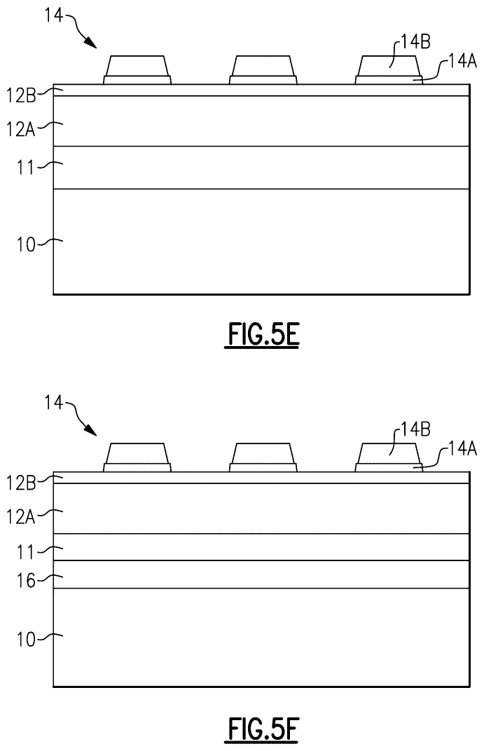

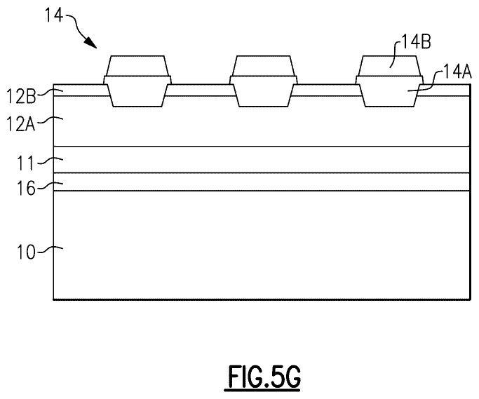

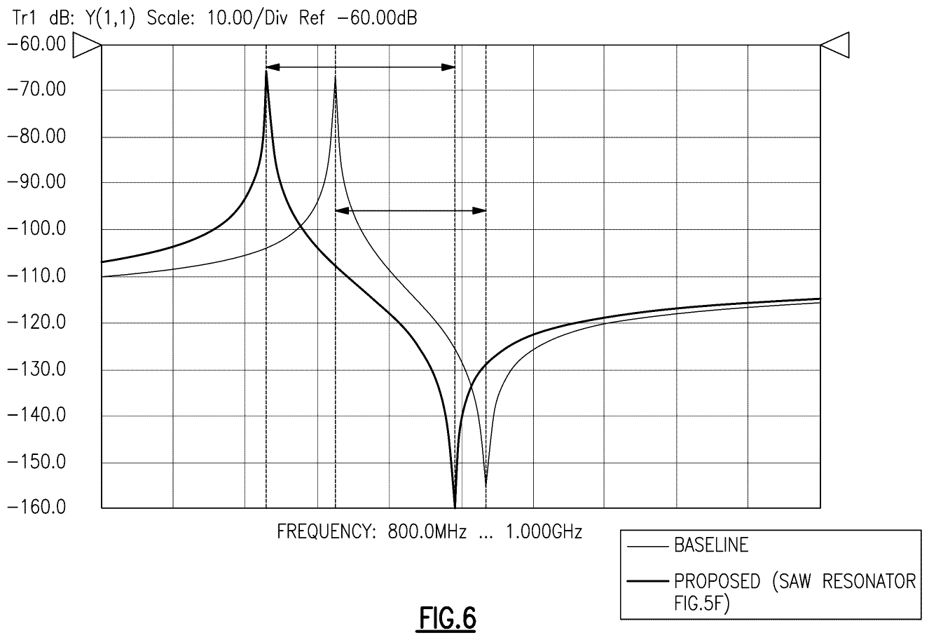

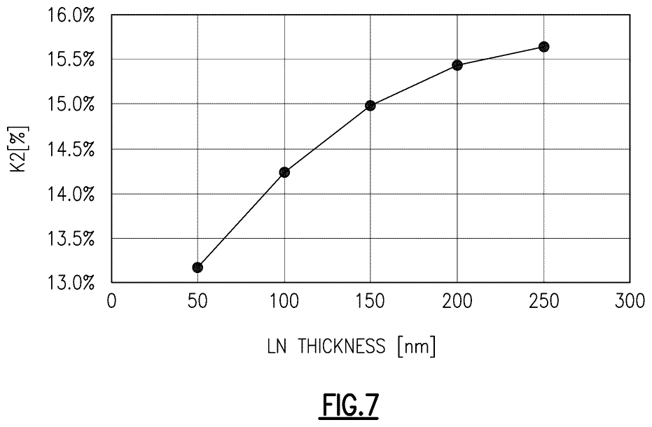

It has been discovered that the k² value of a SAW device as disclosed herein may be further increased by utilizing multiple layers of piezoelectric material. Instead of utilizing a single layer of piezoelectric material 12 as in the SAW device structures shown in FIGS. 1A and 2A-2C, the SAW device structures may include a first layer of piezoelectric material 12A and a second layer of piezoelectric material 12B deposited (for example, epitaxially deposited) on the first layer of piezoelectric material. As shown in FIGS. 5A-5D, this may be done for any of the SAW device structures shown in FIGS. 1A and 2A-2C or other SAW device structures disclosed herein. The first layer of piezoelectric material 12A and the second layer of piezoelectric material 12B may be formed of different lithium-based piezoelectric material. In some embodiments, the first layer of piezoelectric material 12A (the lower layer of piezoelectric material) may be or may comprise lithium tantalate (LT, LiTaO₃) and the second layer of piezoelectric material 12B (the upper layer of piezoelectric material) may be or may comprise lithium niobate (LN, LiNbO₃). In other examples, one of the first or second layers of piezoelectric material may be or may comprise aluminum nitride.

In embodiments including single layer electrode fingers, the electrode fingers may be disposed entirely on top of the second layer of piezoelectric material 12B as shown in FIG. 5A or may be partially buried and extend downward into one or both of the layers of piezoelectric material 12A, 12B as shown in FIGS. 5B and 5C. In embodiments including electrode fingers with multiple metal layers 14A, 14B the entirety of the electrode fingers may be disposed entirely on top of the second layer of piezoelectric material 12B as shown in FIGS. 5E and 5F or one or both of the metal layers 14A, 14B may be partially buried and extend downward into one or both of the layers of piezoelectric material 12A, 12B as shown in FIG. 5D.

In some embodiments, the first layer of piezoelectric material 12A (the lower layer of piezoelectric material) may be thicker than the second layer of piezoelectric material 12B (the upper layer of piezoelectric material). In non-limiting embodiments, the first layer of piezoelectric material 12A may have a thickness of between 300 nm and 1,500 nm and the second layer of piezoelectric material 12B may have a thickness of between 10 nm and 300 nm. In embodiments in which the IDT electrode fingers extend downward into one or both of the layers of piezoelectric material 12A, 12B, the buried portions of the electrode fingers may extend about 10 nm into the one or both of the layers of piezoelectric material 12A, 12B.

In any of the embodiments disclosed herein in which the SAW device structure includes a SiO₂ layer 11 formed on a support substrate 10, a trap-rich layer 16, for example, a layer of poly-silicon may be disposed on top of the support substrate 10 between the support substrate 10 and the SiO₂ layer 11 as shown in the embodiment of FIG. 5F, in which the IDT electrode fingers are not buried in the piezoelectric material, or FIG. 5G, which is similar to the embodiment of FIG. 5D in which the IDT electrode fingers are partially buried in the piezoelectric material. The trap-rich layer may have a thickness of between 200 nm and 2000 nm or between 500 nm and 1500 nm.

FIG. 6 is a graph showing simulated admittance results of a baseline SAW device and the SAW device of FIG. 5F. The baseline SAW device is generally similar to the SAW resonator of FIG. 5F but the baseline SAW device does not include the second layer of piezoelectric material 12B. The baseline SAW device includes a silicon support substrate 10, a 1000 nm thick poly-silicon layer 16 over the silicon support substrate 10, a 1000 nm thick silicon dioxide (SiO₂) layer 11 over the poly-silicon layer 16, a 1000 nm thick 42YX-LT layer 12 over the SiO₂ layer 11, and an interdigital transducer (IDT) electrode 14 having a 200 nm thick molybdenum (Mo) layer 14A and a 200 nm thick aluminum (Al) layer 14B over the Mo layer 14A on the 42YX-LT layer 12. A SAW device such as shown in FIG. 5F used in the simulation includes a silicon layer as the support substrate 10, a 1000 nm thick poly-silicon layer as the trap rich layer 16, a 1000 nm thick silicon dioxide (SiO₂) layer as the functional layer 11, a 1000 nm thick 42YX-LT layer as the first layer of piezoelectric material 12A, a 250 nm thick 42YX-LN layer as the second layer of piezoelectric material 12B, and an interdigital transducer (IDT) electrode 14 having a 200 nm thick molybdenum (Mo) layer 14A and a 200 nm thick aluminum (Al) layer 14B as the acoustic element. For both the base line SAW device and the SAW device as shown in FIG. 5F used in the simulations, the pitch (L) is set to 4 μm and the duty factor is set to 0.5.

The simulation results indicate that inclusion of the second layer of piezoelectric material 12B (the 42YX-LN layer) improves the coupling factor k² while maintaining basic acoustic properties (e.g., low loss, and good temperature coefficient of frequency (TCF)) of the baseline SAW device. Accordingly, the second layer of piezoelectric material 12B can beneficially increase the coupling factor k² without negatively affecting the loss and TCF. The coupling factor k² of the SAW device of FIG. 5F can depend at least partially on, for example, the thickness of the second layer of piezoelectric material 12B and/or cut angles of the first and second layers of piezoelectric material 12A, 12B.

FIG. 7 is a graph showing simulated coupling factor k² results of the SAW device of FIG. 5F simulated at various thicknesses of the second layer of piezoelectric material 12B. The simulation results of FIG. 7 indicate that the coupling factor k² of the SAW device of FIG. 5F increases as the thickness of the second layer of piezoelectric material 12B increases. In some embodiments, the thickness of the second layer of piezoelectric material 12B can be in a range of 50 nm to 250 nm, 50 nm to 200 nm, 100 nm to 250 nm, 100 nm to 200 nm, or 150 nm to 250 nm.

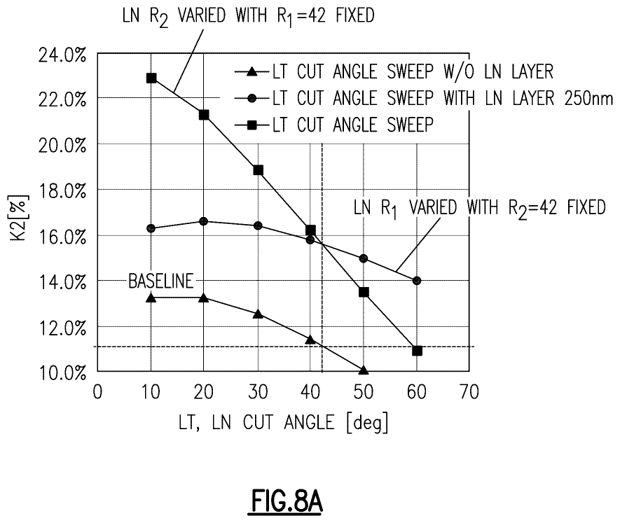

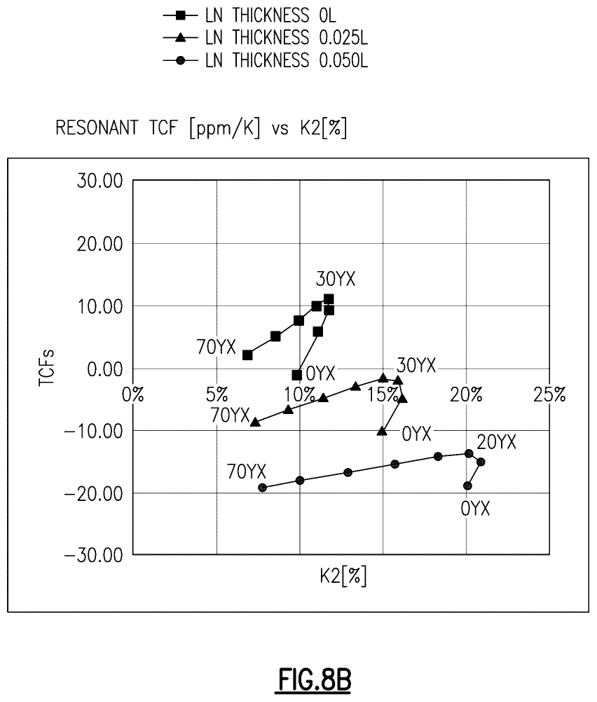

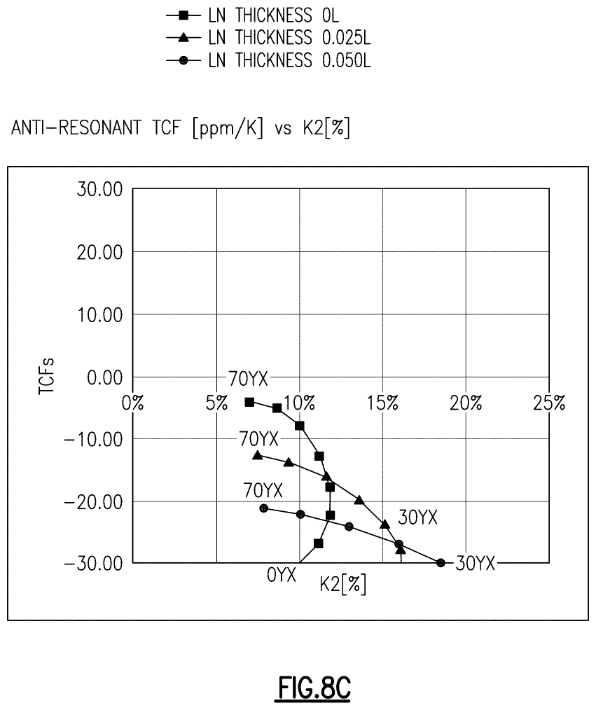

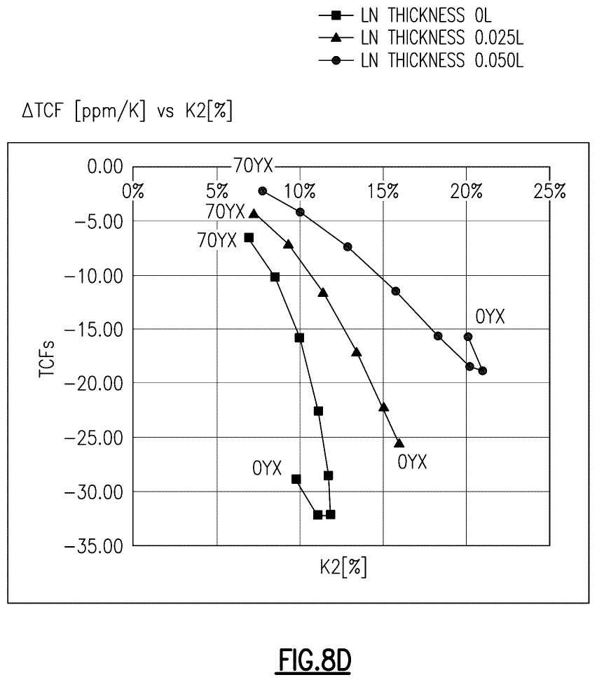

FIG. 8A is a graph showing simulated coupling factor k² results of the baseline SAW device and the SAW device of FIG. 5F simulated with various YX-cut angles of the LT layer and the first and second layers of piezoelectric material 12A, 12B. The simulation results of FIG. 8A indicate that the YX-cut angles of the LT layer and the first and second layers of piezoelectric material 12A, 12B can impact the coupling factor k² of the baseline SAW device and the SAW device of FIG. 5F. In some embodiments, the first layer of piezoelectric material 12A can be a lithium tantalate (LT) layer having a YX-cut angle in a range of 10° to 60°, 20° to 60°, 20° to 50°, 10° to 50°, or 30° to 50°. In some embodiments, the second layer of piezoelectric material 12B can be a lithium niobate (LN) layer having a YX-cut angle in a range of 10° to 60°, 20° to 60°, 20° to 50°, 10° to 50°, or 30° to 50°. In some embodiments, structural and material properties (e.g., thicknesses, cut angles, materials, etc.) of the first and second layers of piezoelectric material 12A, 12B can be adjusted to enable the SAW device to provide desired electrical properties.

FIG. 8B is a graph showing results of simulated resonant temperature coefficient of frequency (TCF) relative to coupling factor k² of the SAW device of FIG. 5F simulated with various YX-cut angles of the first and second layers of piezoelectric material 12A, 12B. FIG. 8C is a graph showing results of simulated anti-resonant temperature coefficient of frequency (TCF) relative to coupling factor k² of the SAW device of FIG. 5F simulated with various YX-cut angles of the first and second layers of piezoelectric material 12A, 12B. FIG. 8D is a graph showing simulated results of difference in resonant temperature coefficient of frequency (TCF) relative to coupling factor k² of the SAW device of FIG. 5F simulated with various YX-cut angles of the first and second layer of piezoelectric material 12A, 12B. In the simulations of FIGS. 8B-8D, the thicknesses of the functional layer 11 and the first layer of piezoelectric material 12A are fixed at 0.25λ, where λ is a wavelength of a surface acoustic wave generated. In some embodiments, the pitch of the IDT electrodes can set the wavelength λ of the surface acoustic wave.

The simulation results of FIGS. 8B-8D indicate that the resonant and anti-resonant temperature coefficient of frequencies (TCFs) and the coupling factor k² can be affected by the cut angles of the first and second layers of piezoelectric material 12A, 12B and the thickness of the second layer of piezoelectric material 12B. The simulation results of FIGS. 8B-8D also indicate that the second layer of piezoelectric material 12B enables a wider coupling factor k² tuning range for the SAW device.

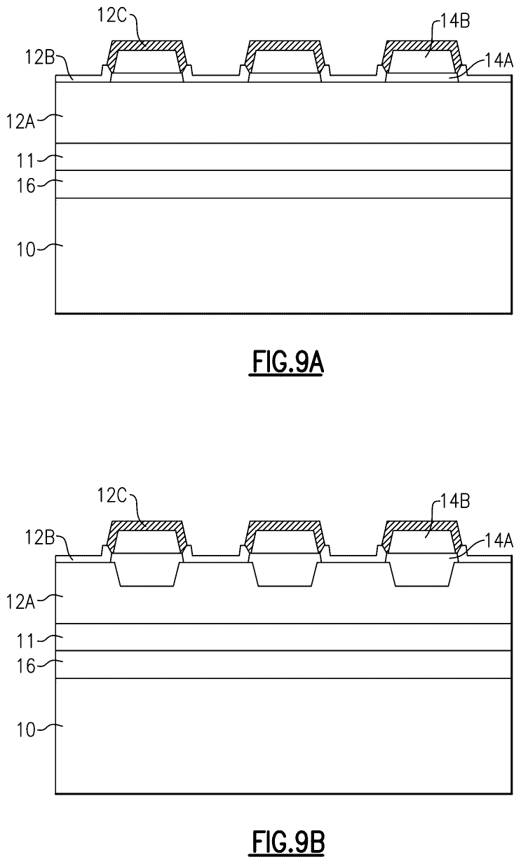

In further embodiments, a third layer of piezoelectric material 12C may be deposited on portions of the SAW device that are not covered by the second layer of piezoelectric material 12B, for example, on the IDT electrode fingers. The third layer of piezoelectric material 12C may be formed of the same material as the second layer of piezoelectric material 12B but may be deposited non-epitaxially, for example, by physical vapor deposition (e.g., sputtering), rather than by epitaxial deposition. FIG. 9A illustrates one embodiment that is similar to the embodiment of FIG. 5F, in which the IDT electrode fingers are disposed on the surface of the second layer of piezoelectric material 12B, with the addition of the third layer of piezoelectric material 12C. FIG. 9B illustrates one embodiment that is similar to the embodiment of FIG. 5G, in which the IDT electrode fingers are partially buried in the layers of piezoelectric material 12A, 12B, with the addition of the third layer of piezoelectric material 12C.

The various embodiments of surface acoustic wave devices described above include support substrates 10 formed of a material such as silicon, AlN, or sapphire and optionally a trap-rich layer 16 formed of, for example, polysilicon. In further embodiments, additional advantages may be achieved by utilizing quartz (crystalline SiO₂) for the support substrate as well as the functional layer 11, and omitting the silicon, AlN, or sapphire support substrate 10 and trap-rich layer 16. These advantages may include providing for additional temperature compensation so that the TCF at both the resonant and antiresonant frequencies of the SAW device is negligible, for example, within ±5 ppm/° C., as well as improving performance of the SAW device by increasing quality factor and removing spurious signals from the path of the main acoustic wave generated in the device. For example, a higher order spurious mode can be suppressed by leakage into a crystal cut angle of the quartz substrate. The quartz cut angle can be in a range from 20° to 52° on R-rotated YX-quartz.

By using the quartz as a substrate instead of certain relatively high impedance substrates, a higher order spurious mode can be leaked into the substrate side of a SAW device. This can be due to an anisotropic feature of quartz. Quartz can behave as a high impedance substrate at limited crystal cut angles. Accordingly, the Q of a SAW device that includes a lithium tantalate layer over a quartz substrate can exhibit an improved Q relative to other devices by trapping an acoustic wave in the lithium tantalate layer. Certain high impedance substrates (e.g., a silicon substrate, an aluminum nitride substrate, or a sapphire substrate), can trap an acoustic wave in a lithium tantalate layer. However, at the same time, higher order spurious mode responses can be trapped in the lithium tantalate layer with such high impedance substrates. Accordingly, higher order spurious responses can appear in a filter response of a filter utilizing such SAW devices in such circumstances. The bulk wave velocity of quartz is less than that of many other high impedance materials, such as silicon, aluminum nitride, and sapphire. Accordingly, a higher order spurious mode response can more easily leak into quartz than for the other high impedance materials. The Q factor associated with a higher mode spurious response can be decreased by leakage in accordance with the principles and advantages discussed herein, and spurious mode impact on filter response can be suppressed.

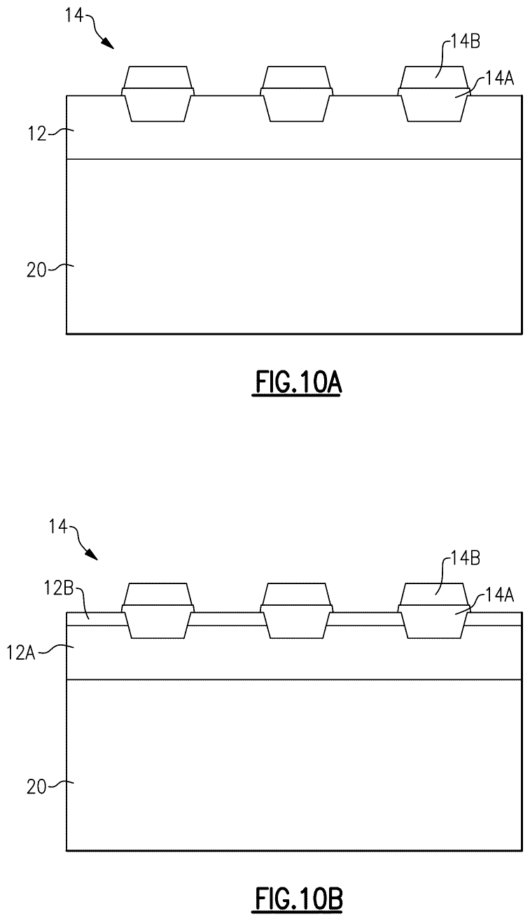

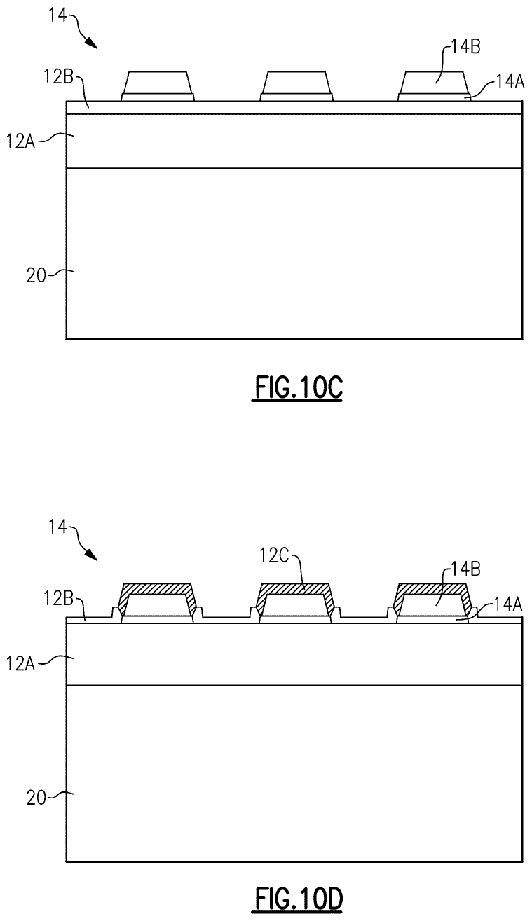

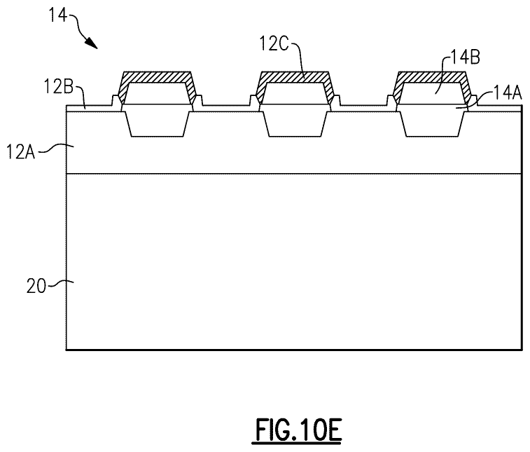

One example of a SAW device including a support substrate consisting of quartz instead of silicon, aluminum nitride, sapphire, etc. is illustrated in FIG. 10A. The SAW device of FIG. 10A is similar to that illustrated in FIG. 2C in that it includes an IDT electrode structure in which the IDT electrodes have lower layers 14A and upper layers 14B and the IDT structure is partially buried in a piezoelectric material structure including a single layer of piezoelectric material 12, e.g., LT. The SAW device of FIG. 10A differs from that illustrated in FIG. 2C, however, because the support substrate 10 and functional layer 11 have been removed and replaced by a layer 20 of quartz. The layer 20 of quartz is utilized as the support substrate in the embodiment illustrated in FIG. 10A. In some embodiments, the layer 20 of quartz may be between 100 μm and 500 μm thick.

Another example of a SAW device including a support substrate consisting of quartz instead of silicon, aluminum nitride, sapphire, etc. is illustrated in FIG. 10B. The SAW device of FIG. 10B is similar to that illustrated in FIG. 5D in that it includes an IDT electrode structure 14 in which the IDT electrodes have lower layers 14A and upper layers 14B and the IDT structure is partially buried in a dual layer piezoelectric material structure including a lower layer of piezoelectric material 12A and an upper layer of piezoelectric material 12B. The SAW device of FIG. 10B differs from that illustrated in FIG. 5D, however, because the support substrate 10 and functional layer 11 have been removed and replaced by a layer 20 of quartz. The layer 20 of quartz is utilized as the support substrate in the embodiment illustrated in FIG. 10B. In some embodiments, the layer 20 of quartz may be between 100 μm and 500 μm thick.

Another example of a SAW device including a support substrate consisting of quartz instead of silicon, aluminum nitride, sapphire, etc. is illustrated in FIG. 10C. The SAW device of FIG. 10C is similar to that illustrated in FIG. 5E in that it includes an IDT electrode structure 14 in which the IDT electrodes have lower layers 14A and upper layers 14B and the IDT structure is disposed on top of a dual layer piezoelectric material structure including a lower layer of piezoelectric material 12A and an upper layer of piezoelectric material 12B. The SAW device of FIG. 10C differs from that illustrated in FIG. 5E, however, because the support substrate 10 and functional layer 11 have been removed and replaced by a layer 20 of quartz. The layer 20 of quartz is utilized as the support substrate in the embodiment illustrated in FIG. 10C. In some embodiments, the layer 20 of quartz may be between 100 μm and 500 μm thick.

Another example of a SAW device including a support substrate consisting of quartz instead of silicon, aluminum nitride, sapphire, etc. is illustrated in FIG. 10D. The SAW device of FIG. 10D is similar to that illustrated in FIG. 9A in that it includes an IDT electrode structure 14 in which the IDT electrodes have lower layers 14A and upper layers 14B and the IDT structure is disposed on top of a dual layer piezoelectric material structure including a lower layer of piezoelectric material 12A and an upper layer of piezoelectric material 12B. A third layer of piezoelectric material 12C is disposed on top of the IDT electrodes. The SAW device of FIG. 10D differs from that illustrated in FIG. 9A, however, because the support substrate 10, trap-rich layer 16, and functional layer 11 have been removed and replaced by a layer 20 of quartz. The layer 20 of quartz is utilized as the support substrate in the embodiment illustrated in FIG. 10C. In some embodiments, the layer 20 of quartz may be between 100 μm and 500 μm thick.

Another example of a SAW device including a support substrate consisting of quartz instead of silicon, aluminum nitride, sapphire, etc. is illustrated in FIG. 10E. The SAW device of FIG. 10E is similar to that illustrated in FIG. 9B in that it includes an IDT electrode structure 14 in which the IDT electrodes have lower layers 14A and upper layers 14B and the IDT structure is partially buried in a dual layer piezoelectric material structure including a lower layer of piezoelectric material 12A and an upper layer of piezoelectric material 12B. A third layer of piezoelectric material 12C is disposed on top of the IDT electrodes. The SAW device of FIG. 10E differs from that illustrated in FIG. 9B, however, because the support substrate 10, trap-rich layer 16, and functional layer 11 have been removed and replaced by a layer 20 of quartz. The layer 20 of quartz is utilized as the support substrate in the embodiment illustrated in FIG. 10D. In some embodiments, the layer 20 of quartz may be between 100 μm and 500 μm thick.

In embodiments of SAW devices having quartz support substrates, such as those illustrated in FIGS. 10A-10E The quartz substrate 20 can have a cut angle in a range from 20° to 52°. As used herein, a “cut angle” of N° refers to an N° rotated Y-cut in a Y-cut X-propagation piezoelectric layer. Accordingly, for a piezoelectric layer with Euler angles (φ, θ, ψ), the “cut angle” in degrees can be θ minus 90°. Embodiments of the SAW device can generate a surface acoustic wave having a wavelength of λ and the thickness H1 of the lithium tantalate layer 12 or 12A can be in a range from 0.15λ to 1.4λ. In some instances, the thickness H1 of the lithium tantalate layer 12 or 12A can be in a range from 0.2λ to 1.2λ. The lithium tantalate layer 12 or 12A can have a cut angle in range from 10° to 50°. This cut angle range can provide desirable k² values. In some embodiments, the lithium tantalate layer 12 or 12A can have a cut angle in a range from 40° to 50°. The lithium tantalate layer 12 or 12A can be bonded to the quartz substrate 20.

In some embodiments, multiple SAW resonators as disclosed herein may be combined into a filter, for example, an RF ladder filter schematically illustrated in FIG. 11 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

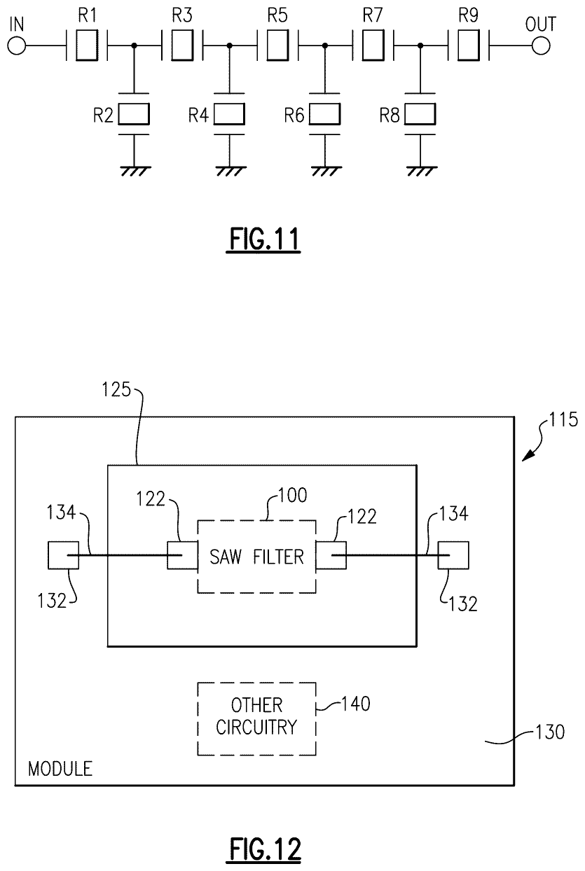

Examples of the SAW devices, e.g., SAW resonators discussed herein can be implemented in a variety of packaged modules. Some example packaged modules will now be discussed in which any suitable principles and advantages of the SAW devices discussed herein can be implemented. FIGS. 12, 13, and 14 are schematic block diagrams of illustrative packaged modules and devices according to certain embodiments.

As discussed above, surface acoustic wave resonators can be used in surface acoustic wave (SAW) RF filters. In turn, a SAW RF filter using one or more surface acoustic wave elements may be incorporated into and packaged as a module that may ultimately be used in an electronic device, such as a wireless communications device, for example. FIG. 12 is a block diagram illustrating one example of a module 115 including a SAW filter 100. The SAW filter 100 may be implemented on one or more die(s) 125 including one or more connection pads 122. For example, the SAW filter 100 may include a connection pad 122 that corresponds to an input contact for the SAW filter and another connection pad 122 that corresponds to an output contact for the SAW filter. The packaged module 115 includes a packaging substrate 130 that is configured to receive a plurality of components, including the die 125. A plurality of connection pads 132 can be disposed on the packaging substrate 130, and the various connection pads 122 of the SAW filter die 125 can be connected to the connection pads 132 on the packaging substrate 130 via electrical connectors 134, which can be solder bumps or wirebonds, for example, to allow for passing of various signals to and from the SAW filter 100. The module 115 may optionally further include other circuitry die 140, for example, one or more additional filter(s), amplifiers, pre-filters, modulators, demodulators, down converters, and the like, as would be known to one of skill in the art of semiconductor fabrication in view of the disclosure herein. In some embodiments, the module 115 can also include one or more packaging structures to, for example, provide protection and facilitate easier handling of the module 115. Such a packaging structure can include an overmold formed over the packaging substrate 130 and dimensioned to substantially encapsulate the various circuits and components thereon.

Various examples and embodiments of the SAW filter 100 can be used in a wide variety of electronic devices. For example, the SAW filter 100 can be used in an antenna duplexer, which itself can be incorporated into a variety of electronic devices, such as RF front-end modules and communication devices.

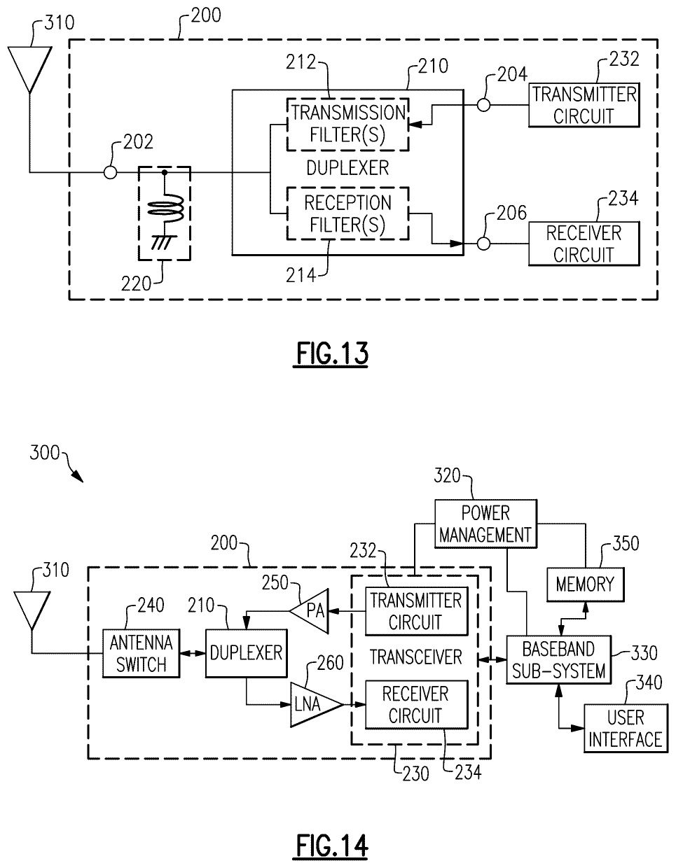

Referring to FIG. 13, there is illustrated a block diagram of one example of a front-end module 200, which may be used in an electronic device such as a wireless communications device (e.g., a mobile phone) for example. The front-end module 200 includes an antenna duplexer 210 having a common node 202, an input node 204, and an output node 206. An antenna 510 is connected to the common node 202.

The antenna duplexer 210 may include one or more transmission filters 212 connected between the input node 204 and the common node 202, and one or more reception filters 214 connected between the common node 202 and the output node 206. The passband(s) of the transmission filter(s) are different from the passband(s) of the reception filters. Examples of the SAW filter 100 can be used to form the transmission filter(s) 212 and/or the reception filter(s) 214. An inductor or other matching component 220 may be connected at the common node 202.

The front-end module 200 further includes a transmitter circuit 232 connected to the input node 204 of the duplexer 210 and a receiver circuit 234 connected to the output node 206 of the duplexer 210. The transmitter circuit 232 can generate signals for transmission via the antenna 310, and the receiver circuit 234 can receive and process signals received via the antenna 310. In some embodiments, the receiver and transmitter circuits are implemented as separate components, as shown in FIG. 13, however, in other embodiments these components may be integrated into a common transceiver circuit or module. As will be appreciated by those skilled in the art, the front-end module 200 may include other components that are not illustrated in FIG. 13 including, but not limited to, switches, electromagnetic couplers, amplifiers, processors, and the like.

FIG. 14 is a block diagram of one example of a wireless device 300 including the antenna duplexer 210 shown in FIG. 13. The wireless device 300 can be a cellular phone, smart phone, tablet, modem, communication network or any other portable or non-portable device configured for voice or data communication. The wireless device 300 can receive and transmit signals from the antenna 310. The wireless device includes an embodiment of a front-end module 200 similar to that discussed above with reference to FIG. 13. The front-end module 200 includes the duplexer 210, as discussed above. In the example shown in FIG. 14 the front-end module 200 further includes an antenna switch 240, which can be configured to switch between different frequency bands or modes, such as transmit and receive modes, for example. In the example illustrated in FIG. 14, the antenna switch 240 is positioned between the duplexer 210 and the antenna 310; however, in other examples the duplexer 210 can be positioned between the antenna switch 240 and the antenna 310. In other examples the antenna switch 240 and the duplexer 210 can be integrated into a single component.

The front-end module 200 includes a transceiver 230 that is configured to generate signals for transmission or to process received signals. The transceiver 230 can include the transmitter circuit 232, which can be connected to the input node 204 of the duplexer 210, and the receiver circuit 234, which can be connected to the output node 206 of the duplexer 210, as shown in the example of FIG. 14.

Signals generated for transmission by the transmitter circuit 232 are received by a power amplifier (PA) module 250, which amplifies the generated signals from the transceiver 230. The power amplifier module 250 can include one or more power amplifiers. The power amplifier module 250 can be used to amplify a wide variety of RF or other frequency-band transmission signals. For example, the power amplifier module 250 can receive an enable signal that can be used to pulse the output of the power amplifier to aid in transmitting a wireless local area network (WLAN) signal or any other suitable pulsed signal. The power amplifier module 250 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 250 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 14, the front-end module 200 may further include a low noise amplifier module 260, which amplifies received signals from the antenna 310 and provides the amplified signals to the receiver circuit 234 of the transceiver 230.

The wireless device 300 of FIG. 14 further includes a power management sub-system 320 that is connected to the transceiver 230 and manages the power for the operation of the wireless device 300. The power management system 320 can also control the operation of a baseband sub-system 330 and various other components of the wireless device 300. The power management system 320 can include, or can be connected to, a battery (not shown) that supplies power for the various components of the wireless device 300. The power management system 320 can further include one or more processors or controllers that can control the transmission of signals, for example. In one embodiment, the baseband sub-system 330 is connected to a user interface 340 to facilitate various input and output of voice and/or data provided to and received from the user. The baseband sub-system 330 can also be connected to memory 350 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A surface acoustic wave (SAW) device comprising:
a quartz substrate;
a layer of a first lithium-based piezoelectric material disposed on an upper surface of the quartz substrate;
a layer of a second lithium-based piezoelectric material formed of a material different from the first lithium-based piezoelectric material disposed on an upper surface of the layer of the first lithium-based piezoelectric material; and
interdigital transducer electrodes disposed on an upper surface of the layer of the second lithium-based piezoelectric material.

2. The SAW device of claim 1 wherein the first lithium-based piezoelectric material is lithium tantalate having a cut angle in a range from 10° to 50°.

3. The SAW device of claim 2 wherein the second lithium-based piezoelectric material is lithium niobate.

4. The SAW device of claim 3 wherein the layer of lithium niobate is thinner than the layer of lithium tantalate and the quartz substrate is thicker than a combined thickness of the layer of lithium niobate is thinner and the layer of lithium tantalate.

5. The SAW device of claim 1 wherein the quartz substrate has a cut angle in a range from 20° to 52°.

6. The SAW device of claim 1 further comprising a layer of the second lithium-based piezoelectric material disposed on upper surfaces of the interdigital transducer electrodes.

7. A surface acoustic wave (SAW) device comprising:
a quartz substrate;
a layer of a first lithium-based piezoelectric material disposed on an upper surface of the quartz substrate; and
interdigital transducer electrodes at least partially buried in the layer of the first lithium-based piezoelectric material.

8. The SAW device of claim 7 wherein the first lithium-based piezoelectric material is lithium tantalate.

9. The SAW device of claim 7 wherein the interdigital transducer electrodes are multi-layer electrodes including a lower layer and an upper layer disposed on an upper surface of the lower layer, the lower layer of the interdigital transducer electrodes at least partially buried within the layer of the first lithium-based piezoelectric material, the upper layer of the interdigital transducer electrodes disposed at a height above an upper surface of the layer of the first lithium-based piezoelectric material.

10. The SAW device of claim 9 further comprising a layer of a second lithium-based piezoelectric material formed of a material different from the first lithium-based piezoelectric material and disposed on an upper surface of the layer of the first lithium-based piezoelectric material.

11. The SAW device of claim 10 wherein the interdigital transducer electrodes are multi-layer electrodes including a lower layer and an upper layer disposed on an upper surface of the lower layer, the lower layer of the interdigital transducer electrodes at least partially buried within the first layer of lithium-based piezoelectric material and the second layer of lithium-based piezoelectric material.

12. The SAW device of claim 10 further comprising a second layer of the second lithium-based piezoelectric material disposed on upper surfaces of the interdigital transducer electrodes.

13. A surface acoustic wave (SAW) device comprising:
a support substrate;
a layer of a first lithium-based piezoelectric material disposed above an upper surface of the support substrate;
a layer of a second lithium-based piezoelectric material formed of a material different from the first lithium-based piezoelectric material disposed on an upper surface of the layer of the first lithium-based piezoelectric material; and
interdigital transducer electrodes at least partially buried within the layer of the second lithium-based piezoelectric material.

14. The SAW device of claim 13 wherein the first lithium-based piezoelectric material is lithium tantalate and the second lithium-based piezoelectric material is lithium niobate.

15. The SAW device of claim 13 wherein the interdigital transducer electrodes are at least partially buried within the layer of the first lithium-based piezoelectric material and the layer of the second lithium-based piezoelectric material.

16. The SAW device of claim 13 wherein the interdigital transducer electrodes are multi-layer electrodes including a lower layer and an upper layer disposed on an upper surface of the lower layer, the lower layer of the interdigital transducer electrodes at least partially buried within the layer of the second lithium-based piezoelectric material, the upper layer of the interdigital transducer electrodes disposed at a height above an upper surface of the layer of the second lithium-based piezoelectric material.

17. The SAW device of claim 13 wherein the interdigital transducer electrodes are multi-layer electrodes including a lower layer and an upper layer disposed on an upper surface of the lower layer, the lower layer of the interdigital transducer electrodes at least partially buried within the layer of the first lithium-based piezoelectric material and the layer of the second lithium-based piezoelectric material, the upper layer of the interdigital transducer electrodes disposed at a height above an upper surface of the layer of the second lithium-based piezoelectric material.

18. A radio frequency filter including the SAW device of claim 13.

19. A radio frequency device module including the radio frequency filter of claim 18.

20. A radio frequency device including the radio frequency device module of claim 19.
